(19) United States
(12) Patent Application Publication
(10) Pub. No.: US 2020/0343856 A1
(43) Pub. Date: Oct. 29, 2020

(54) POST-COMPENSATION FOR CRYSTAL OSCILLATOR THERMAL DRIFT

(71) Applicant: GOODIX TECHNOLOGY INC., San Diego, CA (US)

(72) Inventors: Mohamed ABOUDINA, San Diego, CA (US); Ahmed EMIRA, San Diego, CA (US); Amr Abuellil, San Diego, CA (US)

(21) Appl. No.: 16/575,410

(22) Filed: Sep. 19, 2019

Related U.S. Application Data
(60) Provisional application No. 62/838,916, filed on Apr. 25, 2019.

(51) Int. Cl. H03B 5/04; H03L 7/099; H03L 1/02

(52) U.S. Cl. CPC H03B 5/04; H03L 1/026; H03L 7/0992

(57) ABSTRACT

Techniques are described for post-compensation of frequency drift due to changes in crystal oscillator temperature during operation. For example, a clock system is coupled with a crystal oscillator, and can use a reference clock signal from the crystal oscillator to generate an output clock signal using a clock generator. The clock system can monitor an electrical characteristic of a thermal component integrated with the oscillator, which it can map deterministically to a thermal value indicating a temperature of a crystal component of the oscillator. The clock system can then map the temperature deterministically to a frequency shift of the oscillator away from a nominal value. The clock system can then generate a post-compensation signal that directs the clock generator to shift the frequency of the clock output signal so as to compensate for at least a portion of the frequency drift.

### CROSS-REFERENCES TO RELATED APPLICATIONS

This application claims the benefit of U.S. Provisional Patent Application No. 62/838,916, filed on Apr. 25, 2019, the content of which is incorporated by reference in its entirety.

### FIELD

The invention relates generally to transceivers. More particularly, embodiments relate to post-compensation of frequency drift due to changes in crystal oscillator temperature during operation.

### BACKGROUND

Various types of oscillators are commonly used to provide a reference signal for use within electronic applications. Their piezoelectric properties allow them to be a frequency-determining element in electronic circuits. A crystal oscillator, particularly one made of quartz crystal, is distorted by an electric field when voltage is applied to an electrode near or on the crystal. This property is known as electrostriction or inverse piezoelectricity. When the field is removed, the quartz, which oscillates in a precise frequency, generates an electric field as it returns to its previous shape, and this can generate an oscillating voltage that can be used as a precise clock signal.

In some applications, the crystal oscillator can change temperature during operation, and such a temperature change can cause drift in the frequency at which the crystal is oscillating. In many instances, the drift tends to be small enough that the oscillating frequency remains within acceptable limits for the application. In other instances, however, the drift tends to be too large to keep the oscillating frequency within acceptable limits for the application. For example, to comply with applicable standards, a narrow-band Internet of Things (NB-IoT) transmitter may be designed to transmit at a relatively high power (e.g., 15 to 23 dBm) and within a relatively tight bandwidth. Such a high-power transmission can tend to heat the crystal, which can cause frequency drift; and even a small drift may shift the transmission frequency out of the tight bandwidth.

Some conventional approaches to addressing such thermal drift involve use of specialized oscillator components, such as temperature-compensated crystal oscillators (TCXOs). TCXOs integrate a large number of components with the crystal oscillator to effectively detect temperature changes and to pre-compensate for those changes. The pre-compensating seeks to pull the crystal oscillator back to its desired frequency, so that the output frequency of the TCXO stays more constant over a larger range of temperatures, as compared to a typical (non-compensated) crystal oscillator. While TCXOs can be effective, they tend to be large, power hungry, and expensive; and can often cause the oscillator to operate in sub-optimal conditions.

### BRIEF SUMMARY OF THE INVENTION

Embodiments provide circuits, devices, and methods for post-compensation of frequency drift due to changes in crystal oscillator temperature during operation. For example, a clock system is coupled with a crystal oscillator, and can use a reference clock signal from the crystal oscillator to generate an output clock signal using a clock generator. The clock system can use on-chip components to monitor an electrical characteristic of a thermal component integrated with the off-chip crystal component of the oscillator, which it can map deterministically to a thermal value indicating a temperature of the crystal component (e.g., the off-chip crystal component of the oscillator is likely to have a different temperature than the on-chip oscillator circuit components). The clock system can then map the temperature deterministically to a frequency shift of the oscillator away from a nominal value. The clock system can then generate a post-compensation signal that directs the clock generator to shift the frequency of the clock output signal so as to compensate for at least a portion of the frequency drift of the oscillator.

According to one set of embodiments, a clock system is provided. The system includes: a clock generator to couple with an oscillator circuit and to generate a clock output signal at an output frequency responsive to receiving, from the oscillator circuit, a clock reference signal at a reference frequency, the clock reference signal generated by the oscillator circuit responsive to resonant oscillation of a crystal component coupled to the oscillator circuit; a measurement subsystem to couple with a thermal component to measure an electrical domain level of the thermal component; a mapping subsystem coupled with the measurement subsystem to: generate a thermal domain signal corresponding to the electrical domain level in accordance with stored electrical-to-thermal mapping data for the thermal component, such that the thermal domain signal indicates a temperature of the thermal component, the thermal component being disposed in proximity to the crystal component, such that a change in temperature of the thermal component indicates a corresponding change in temperature of the crystal component; and generate a frequency domain signal corresponding to the thermal domain signal in accordance with stored thermal-to-frequency mapping data, such that the frequency domain signal indicates a frequency drift of the clock reference signal away from the reference frequency; and a post-compensation subsystem, coupled with the mapping subsystem and the clock generator, to output a post-compensation signal to the clock generator, such that the post-compensation signal corresponds to the frequency domain signal and directs the clock generator to shift the output frequency so as to compensate for at least a portion of the frequency drift.

According to another set of embodiments, a transmitter system is provided. The transmitter system includes: a crystal system having, integrated therein, a crystal component and a thermistor; an oscillator circuit coupled with the crystal component to generate a clock reference signal at a reference frequency responsive to resonant oscillation of the crystal component; and a clock system. The clock system includes: a clock generator to couple with the oscillator circuit to generate a carrier signal at a carrier frequency responsive to receiving the clock reference signal from the oscillator circuit; a measurement subsystem to couple with the thermistor to measure an electrical domain level indicating a resistance of the thermistor; a mapping subsystem coupled with the measurement subsystem to generate a thermal domain signal indicating a temperature of the crystal component as a function of the resistance of the thermistor, and to generate a frequency domain signal indicating a frequency drift of the clock reference signal away from the reference frequency as a function of the temperature; and a post-compensation subsystem, coupled with the mapping subsystem and the clock generator, to output a post-compensation signal to the clock generator to direct the clock generator to shift the carrier frequency so as to compensate for at least a portion of the frequency drift in accordance with the frequency domain signal.

According to another set of embodiments, a method is provided for post-compensation of frequency drift in an oscillator circuit that outputs a clock reference signal at a reference frequency, such that the clock reference signal is usable by a clock circuit to generate a clock output signal at an output frequency. The method includes: measuring an electrical domain level of an oscillator system comprising a crystal component, a thermal component, and an oscillator circuit; generating a thermal domain signal corresponding to the electrical domain level in accordance with stored electrical-to-thermal mapping data, such that the thermal domain signal indicates a temperature of the crystal component; generating a frequency domain signal corresponding to the thermal domain signal in accordance with stored thermal-to-frequency mapping data, such that the frequency domain signal indicates a frequency drift of the clock reference signal away from the reference frequency; and outputting a post-compensation signal to the clock circuit, such that the post-compensation signal corresponds to the frequency domain signal and directs the clock output signal to shift the output frequency so as to compensate for at least a portion of the frequency drift.

### BRIEF DESCRIPTION OF THE DRAWINGS

The accompanying drawings, referred to herein and constituting a part hereof, illustrate embodiments of the disclosure. The drawings together with the description serve to explain the principles of the invention.

FIG. 1 shows a block diagram of an illustrative transceiver circuit having receiver and transmitter portions for use with embodiments described herein;

FIG. 2 shows an illustrative conventional temperature-compensated crystal oscillators;

FIG. 3 shows a block diagram of an illustrative clock signal generation system, according to various embodiments;

FIGS. 4A-4D show representative plots of various electrical and thermal characteristics exploited by embodiments described herein;

FIG. 5 shows a block diagram of an illustrative implementation of a portion of a clock system, according to some embodiments; and

FIG. 6 shows a flow diagram of an illustrative method for post-compensation of frequency drift in an oscillator circuit, according to various embodiments.

In the appended figures, similar components and/or features can have the same reference label. Further, various components of the same type can be distinguished by following the reference label by a second label that distinguishes among the similar components. If only the first reference label is used in the specification, the description is applicable to any one of the similar components having the same first reference label irrespective of the second reference label.

### DETAILED DESCRIPTION OF THE INVENTION

In the following description, numerous specific details are provided for a thorough understanding of the present invention. However, it should be appreciated by those of skill in the art that the present invention may be realized without one or more of these details. In other examples, features and techniques known in the art will not be described for purposes of brevity.

Crystal oscillators are commonly used to provide a reference clock signal in electronic applications, such as in transceivers. For example, a crystal oscillator of quartz crystal, is distorted by an electric field when voltage is applied to an electrode near or on the crystal; and when the field is removed, the quartz, which oscillates in a precise frequency, generates an electric field as it returns to its previous shape. This can generate an oscillating voltage that can be used as a precise reference clock signal.

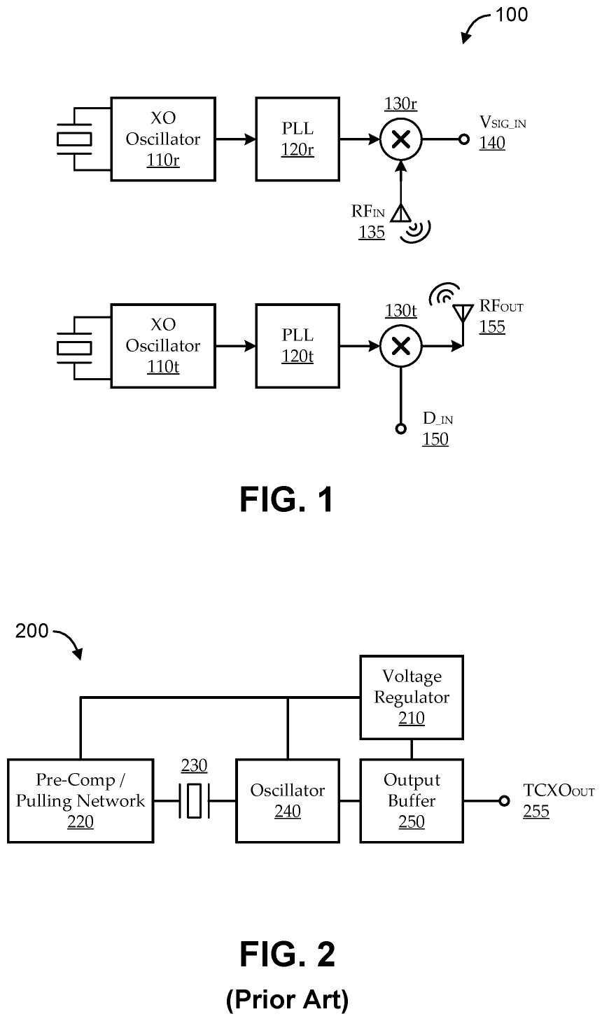

For the sake of context, FIG. 1 shows a block diagram of an illustrative transceiver circuit 100 having receiver and transmitter portions for use with embodiments described herein. In the transmitter portion, a transmitter-side crystal oscillator circuit 110t is used to generate a reference transmitter clock signal. A transmitter-side phase-locked loop (PLL) 120t can be coupled to the transmitter-side crystal oscillator circuit 110t to generate a transmitter-side carrier signal at a carrier frequency that is a multiple (integer and/or fractional) of the reference transmitter clock signal frequency. A transmitter-side modulator (e.g., a multiplier) 130t can receive a data signal 150, and can modulate the transmitter-side carrier signal as a function of the data signal 150. The modulated signal can be transmitted as a radiofrequency output signal 155 via an antenna or other suitable transmission channel.

In the receiver portion, a receiver-side crystal oscillator circuit 110r is used to generate a reference receiver clock signal (e.g., which may be substantially equal to the reference transmitter clock signal). A receiver-side phase-locked loop (PLL) 120r can be coupled to the receiver-side crystal oscillator circuit 110r to generate a receiver-side carrier signal at a carrier frequency that is a multiple (integer and/or fractional) of the reference receiver clock signal frequency. Setting the frequency of the receiver-side carrier signal to be substantially the same as the frequency of the transmitter-side carrier signal can cause the receiver to be “tuned to” transmissions from the transmitter. A receiver-side modulator 130r (or demodulator) can receive the radiofrequency output signal 155, and can demodulate the radiofrequency output signal 155 as a function of the receiver-side carrier signal, thereby recovering the data signal 150. The recovered data signal can be output by the receiver as a received data signal 140.

In some applications, application-specific specifications can impose strict operating conditions, requirements, and/or limits on such a transceiver circuit 100. For example, narrow-band Internet of Things (NB-IoT) is a communication technology developed for so-called Internet of Things devices, which seeks to transmit over a wide area at low power (e.g., referred to as a Low Power Wide Area (LPWA) technology). For example, such NB-IoT transmissions are typically at relatively high power levels (e.g., 15 to 23 dBm), though only in short bursts (e.g., 256 milliseconds); so that the transmission power is relatively low on average. As described above, the transmission frequency can depend on the reference set by the crystal oscillator (e.g., transmitter-side crystal oscillator 110t), and the frequency accuracy of the transmitter can thus depend on the accuracy of the frequency reference set by the crystal oscillator.

Many NB-IoT applications can require communications to remain within a very tight bandwidth (e.g., 0.1 parts-per-million (ppm) of the carrier frequency). Transmitting at such high power levels can tend to heat the transmission circuit, which can heat the crystal oscillator. Though crystal oscillators can have a highly stable frequency response, the frequency response can tend to vary with temperature. Even over a short burst transmission window, the temperature of a crystal oscillator in a NB-IoT transmitter can change enough to cause its frequency response to drift outside of the tight bandwidth specification (e.g., by more than 0.1 ppm) imposed by NB-IoT, or other applications and/or standards.

Some conventional approaches to addressing such thermal drift involve use of specialized oscillator components, such as temperature-compensated crystal oscillators. For added clarity, FIG. 2 shows an illustrative conventional temperature-compensated crystal oscillators (TCXO) 200. As illustrated, the TCXO 200 integrates a large number of components with a crystal oscillator 230 to effectively detect temperature changes and to pre-compensate for those changes. The pre-compensating seeks to pull the crystal oscillator back to its desired frequency, so that the output frequency of the TCXO 200 stays relatively constant over a larger range of temperatures, as compared to a typical (non-compensated) crystal oscillator.

For example, as illustrated, a conventional TCXO 200 can generate an output signal (TCXO_{OUT}) 255 by integrating a voltage regulator 210, a pre-compensation network 220, an oscillator circuit 240, and an output buffer 250 around a crystal oscillator 230. The voltage regulator 210 can generally control a source voltage so as to limit the impact of external voltage changes on the frequency of TCXO_{OUT} 255 (and without introducing any additional temperature impacts). The pre-compensation network 220 can include a compensation lookup circuit and a pulling network. For example, the compensation lookup circuit can sense a temperature in the TCXO 200, and can output a signal typically in accordance with an inverse of an approximated temperature frequency response curve for the crystal oscillator 230. The pulling network can then use the signal from the compensation lookup circuit to pull the frequency of the crystal oscillator 230 in a manner that compensates for temperature-related frequency drifts. For example, the pulling network uses varactor diodes, filters, and other components to directly affect the oscillation of the crystal oscillator 230. The crystal oscillator 230 can then oscillate in accordance with the pulling from the pulling network and components of the oscillator circuit 240 (e.g., which can provide a proper drive voltage, filtering, etc.). The output buffer 250 can then provide amplification, isolation (e.g., impedance matching), and/or other features to the output, so that TCXO_{OUT} 255 is not affected by external loads and other conditions.

Such TCXOs 200, while generally effective, tend to have a number of limitations. One limitation is that TCXOs 200 tend to be relatively large and power hungry, as compared to other crystal oscillator implementations. Another limitation is that the pre-compensation can cause the oscillator to operate in sub-optimal conditions. In general, operation of a crystal oscillator is most optimal when it is oscillating in steady state at its natural resonant frequency. At a particular temperature (or over a temperature range), that natural resonant frequency corresponds to a nominal frequency of the crystal oscillator. As described herein, that natural resonant frequency can shift away from the nominal frequency as the temperature of the crystal oscillator changes; and the role of components of the TCXO 200 (e.g., the pre-compensation network 220) is to pull the frequency of the crystal oscillator back to the nominal frequency. However, pulling towards the nominal frequency also pulls the crystal oscillator away from its natural resonant frequency at that temperature, thereby pulling the crystal oscillator away from its optimal operating point at that temperature. Further, such TXCOs 200 are often designed so that components of the pulling network (e.g., the varactor) tend to operate with minimal power consumption when the TCXO 220 is at an optimal operating point. However, sub-optimal operation of the TCXO 200 can cause the pulling network to vary load capacitance, thereby failing to operate with minimum power consumption.

Embodiments described herein seek to provide thermally stable oscillation from a crystal oscillator-based clock circuit without relying on conventional pre-compensation approaches, such as in TCXOs. Instead, embodiments employ a novel post-compensation approach. Such an approach can yield a stable frequency response over a large temperature range, while permitting the crystal oscillator to oscillate at an optimal operating point.

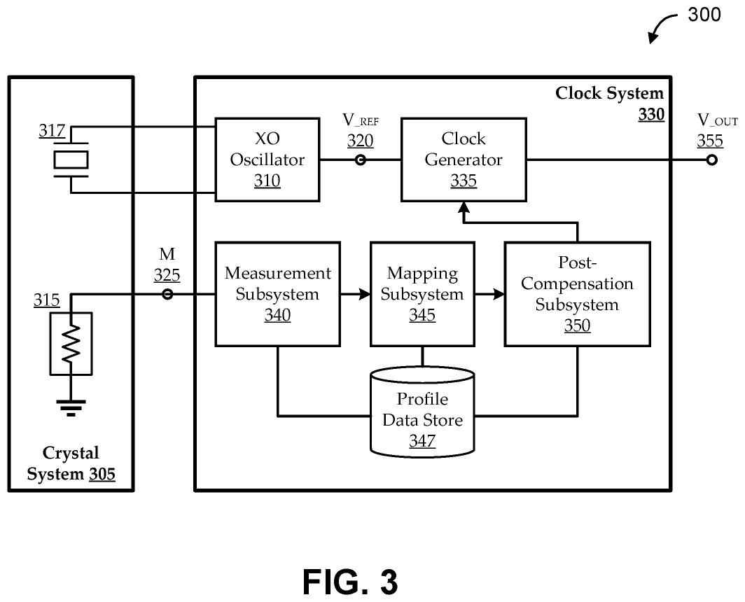

FIG. 3 shows a block diagram of an illustrative clock signal generation system 300, according to various embodiments. The clock signal generation system 300 can include a clock system 330 and an crystal system 305. The crystal system 305 can include a crystal component 317 and a thermal component 315. As described herein, the crystal component 317 can include a quartz crystal, or any other crystal that undergoes desirable electrostriction, inverse piezoelectricity, or the like (i.e., such that a frequency-stable resonance can be electrically stimulated). The crystal component 317 can be coupled with an oscillator circuit 310, which can include any suitable components to generate a stable reference signal from the crystal component 317. For example, the oscillator circuit 310 can include a drive circuit to apply controlled, particular stimulation and drive voltages across the crystal component 317.

The thermal component 315 operates to have one or more electrical characteristic that change as a temperature of the thermal component 315 changes. For example, the thermal component 315 can be implemented as a thermistor, which has a resistance that changes deterministically as a function of temperature. The thermal component 315 is disposed sufficiently adjacent to (e.g., in close enough proximity to) the crystal component 317, such that a temperature change of the thermal component 315 can be used as a measurement of a corresponding temperature change of the crystal component 317. As illustrated, in some implementations, the crystal component 317 and the thermal component 315 are integrated onto a single crystal system 305 (e.g., a package), and/or are integrated within a single component housing.

Embodiments of the clock system 330 can include a clock generator 335, a measurement subsystem 340, a mapping subsystem 345, and a post-compensation subsystem 350. As illustrated, embodiments of the clock system 330 can further include the oscillator circuit 310. Embodiments of the clock generator 335 can couple with the crystal oscillator circuit 310 of the crystal system 305, for example, via a clock reference node 320. During operation, the signal at clock reference node 320 is a clock reference signal generated by the crystal component 317 and the oscillator circuit 310 as a reference frequency. Embodiments of the clock generator 335 can generate a clock output signal (at clock output node 355) at an output frequency that is responsive to the clock reference signal received at the reference frequency at clock reference node 320. In some embodiments, the clock generator 335 includes a phase-locked loop (PLL) that generates the clock output signal in such a way that the output frequency is locked to a multiple of the reference frequency. For example, the PLL includes a divider block that divides frequency of the clock output signal by a dividing value, and feeds back the divided frequency to a comparison block at an input side of the PLL. The comparison block can compare the fed-back, divided frequency with the reference frequency. By locking the fed-back, divided frequency to the reference frequency, the PLL can effectively lock the output frequency to a multiple of the reference frequency corresponding to the dividing value. For example, if the dividing value is N.F (where N is an integer component, and F is a fractional component), the output frequency can be locked to N.F times the reference frequency. As described above, however, a drift in the reference frequency seen at clock reference node 320 can cause a corresponding drift in the output frequency seen at clock output node 355. In fact, the corresponding drift in the output frequency seen at clock output node 355 can be appreciably greater, as it the output frequency is typically a multiple of the reference frequency (e.g., the output frequency drift can be N.F times the reference frequency drift).

Accordingly, other components of the clock system 330 seek to post-compensate for such a frequency drift. In particular, embodiments can implement such post-compensation without intervening in operation of the crystal component 317 or the oscillator circuit 310. Embodiments of the measurement subsystem 340 can couple with the thermal component 315 of the crystal system 305 to measure an electrical domain level of the thermal component 315. For example, the measurement subsystem 340 can be coupled with the thermal component 315 via a measurement node 325. During operation of the crystal system 305, a signal at the measurement node 325 can correspond to the electrical domain level of the thermal component 315. The electrical domain level measured at the measurement node 325 can be a current level, a voltage level, or any other suitable electrical domain level. In some implementations, the thermal component 315 is a thermistor, and embodiments of the measurement subsystem 340 can include a controllable current source to drive a known current through the thermistor. In such an implementation, the electrical domain level measured at the measurement node 325 is a voltage across the thermistor.

Embodiments of the mapping subsystem 345 can be coupled with the measurement subsystem to generate a thermal domain signal corresponding to the electrical domain level in accordance with electrical-to-thermal mapping data for the thermal component 315. In particular, the thermal domain signal is generated to indicate a temperature of the crystal component 317 (e.g., to indicate a temperature of the thermal component 315, which acts as a suitable measurement of a temperature of the crystal component 317). In some implementations, the measurement subsystem 340 generates electrical measurements (e.g., voltage and current measurements) that can be used to derive a resistance of the thermal component 315, and the thermal component 315 can manifest a predetermined relationship between its resistance and its temperature (i.e., its resistance changes deterministically with its temperature). The change in resistance and/or temperature can be expressed in any suitable manner, for example, as an non-relative value (e.g., as a resistance and/or temperature value), or as a relative value (e.g., as a magnitude change in resistance and/or temperature, as a percentage or other change in resistance and/or temperature, etc.).

Embodiments of the mapping subsystem 345 can also generate a frequency domain signal corresponding to the thermal domain signal in accordance with thermal-to-frequency mapping data for the crystal component 317. For example, the crystal component 317 can manifest a predetermined relationship between changes in its temperature and changes in its oscillating frequency. The change in oscillating frequency can be expressed in any suitable manner to indicates a frequency drift of the clock reference signal away from the reference frequency, for example, as a non-relative resonant frequency, as an amount of drift away from a nominal resonant frequency, etc. In one implementation, the change in oscillating frequency is expressed as a deviation from a nominal frequency, measured in parts per million (ppm). For example, if the crystal component 317 is designed to oscillate nominally at 500 Megahertz, a drift of 20 ppm can correspond to a drift of 10 Kilohertz. For many crystal oscillators, the frequency drift over temperature can be approximated by a polynomial of third or higher order, and many such crystal oscillators can manifest frequency drifts of plus or minus 20 ppm or more over a typical operating temperature range.

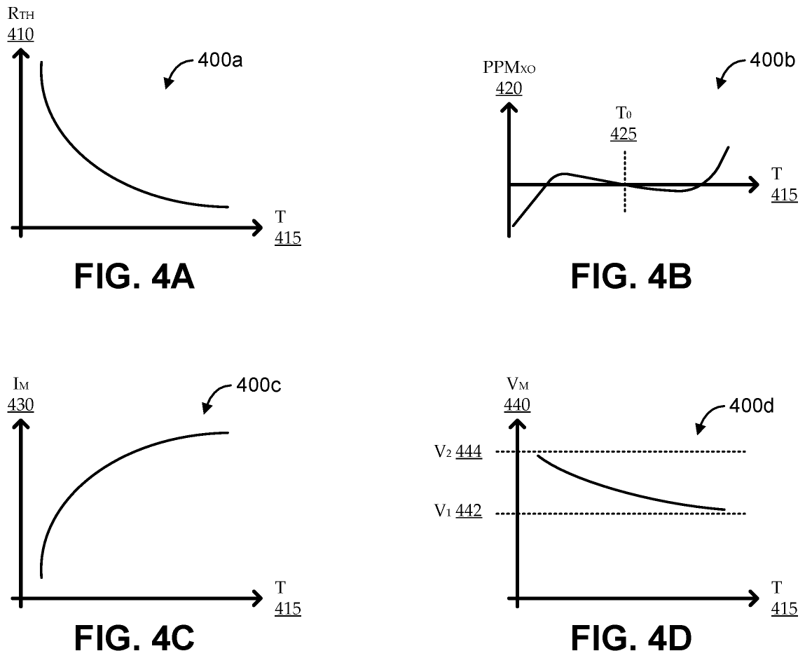

For the sake of illustration, FIGS. 4A-4D show representative plots 400 of various electrical and thermal characteristics exploited by embodiments described herein. FIG. 4A shows an illustrative plot 400a of resistance 410 versus temperature 415 for a typical thermistor, such as an implementation of thermal component 315 of FIG. 3. As the temperature 415 of the thermistor increases, the resistance 410 tends to decrease along a curve approximated by an exponential decay function. This functional relationship is typically deterministic in a particular thermistor component, such that the relationship is predictable, repeatable, measurable, etc.

FIG. 4B shows an illustrative plot 400b of relative frequency drift 420 versus temperature 415 for a typical crystal component, such as an implementation of the crystal component 317 of FIG. 3. As the temperature 415 of the crystal component increases, its resonant frequency tends to change along a curve approximated by a polynomial function. For example, at some nominal operating temperature, T₀ 425 (e.g., 20 degrees Celsius), the resonant frequency is at a nominal frequency, indicated as zero ppm of drift. As the temperature increases or decreases over some range, the resonant frequency of the crystal component tends to drift away from the nominal frequency. For responses of higher order (e.g., third-order, fifth-order, or other polynomial response), there may be portions of an temperature range in which the resonant frequency tends to drift back toward, or even return to, the nominal frequency. This functional relationship is typically deterministic in a particular crystal component, such that the relationship is predictable, repeatable, measurable, etc.

As described with reference to FIG. 3, some embodiments of the measurement subsystem 340 can inject a known current into the thermal component 315 to obtain a voltage measurement at the measurement node 325. Using the known current and the measured voltage, the resistance of the thermal component 315 can be derived by Ohm's law (voltage equals current times resistance); which can permit derivation of the temperature, in accordance with the plot 400a in FIG. 4A. In some such embodiments, it is desirable to obtain a voltage level that has a well-defined, relatively linear response over a large range in thermal component 315 resistance 410 (i.e., over a large range in temperature 415). However, because of the proportional relationship between voltage, current, and resistance in a resistive component, such as a thermistor, injecting the same current at all temperatures 415 will yield a non-linear voltage response across temperature.

As such, some implementations of the measurement subsystem 340 inject a current at a level according to a function that is substantially an inverse of the functional relationship in FIG. 4A. Such an implementation is represented by the plot 400c of FIG. 4C, which shows a representative current injection curve for different temperatures. As shown, as the temperature 415 of the crystal component 317 increases, more current is injected. The current 420 versus temperature 415 curve can follow a logarithmic growth response that substantially corresponds to an inverse of the exponential decay response of the resistance 410 versus temperature 415 curve for the thermal component 315. Injecting current in such a way can yield a voltage response curve, such as the one shown in FIG. 4D. FIG. 4D shows an illustrative plot 400d of measured voltage 440 versus temperature 415, such as could be measured at the measurement node 325 of FIG. 3 in response to injecting current in accordance with FIG. 4C. The injected current 430 can be controlled to yield a particular measured voltage 440 value at each temperature 415 in accordance with Ohm's law. As such, the resulting voltage response plot 400d can be increasing or decreasing, linear or non-linear, etc. (a decreasing, substantially linear response is shown).

Thus, some embodiments of the measurement subsystem 340 can inject a known current in accordance with a predetermined curve (e.g., plot 400c). The measurement subsystem 340 can measure the voltage across the thermal component 315 responsive to the injected current. Using a predetermined voltage response curve (e.g., 400d), the measured voltage can be used to determine a present temperature of the thermal component 315, which corresponds to the present temperature of the crystal component 317. Having derived a present temperature for the crystal component 317, the mapping subsystem 345 can use a predetermined thermal drift response curve (e.g., 400b) to determine an amount (e.g., magnitude and direction) by which the frequency of the crystal component 317 (e.g., and the corresponding reference frequency generated at the output of the oscillator circuit 310) has drifted away from nominal at the present temperature.

Returning to FIG. 3, the various curves (e.g., including those described with reference to FIGS. 4A-4D) can be obtained in any suitable manner. In some embodiments, some or all of the curves can be determined from specifications of particular components. For example, the frequency drift over temperature for a particular crystal component 317 can be listed on a data sheet for that component. In other embodiments, some or all of the curves can be measured prior to, and/or after, integration of the component in the clock signal generation system 300 (e.g., as part of a test bench setup, as part of a startup subroutine for the clock signal generation system 300, etc. For example, a test bench can be used to controllably adjust the temperature of the thermal component 315, and resistance values can be recorded across the tested temperature range.

Some or all of the curves can be stored for use by components of the clock signal generation system 300. In some implementations, the clock system 330 includes a profile data store 347. The profile data store 347 can be implemented as a separate component, or as part of another component (e.g., as part of the measurement subsystem 340 and/or as part of the mapping subsystem 345). In some implementations, the profile data store 347 includes one or more lookup tables. In other implementations, the profile data store 347 is implemented as one or more state machines. In still other embodiments, the profile data store 347 includes a relational database, or other suitable data structure. As an example, the measurement subsystem 340 can measure the electrical domain level of the thermal component 315 by injecting a current level (or asserting a voltage level) in accordance with a profile stored in the profile data store 347; and obtaining the electrical domain level measurement of the thermal component 315 in response thereto. The measurement subsystem 340 can then provide the electrical domain level measurement to the mapping subsystem 345, which can use stored profiles from the profile data store 347 to map the electrical domain level measurement to frequency drift. For example, the mapping subsystem 345 can use stored electrical-to-thermal mapping data for the thermal component 315 (e.g., a resistance versus temperature curve for a thermistor) to map the electrical domain level to a temperature, indicated by the thermal domain signal. The mapping subsystem 345 can then use stored thermal-to-frequency mapping data for the crystal component 317 to map the temperature to a change in its oscillating frequency (i.e., to a frequency drift), as indicated by the frequency domain signal.

The post-compensation subsystem 350 can be coupled with the mapping subsystem 345 to receive the frequency domain signal, and the post-compensation subsystem 350 can also be coupled with the clock generator 335. Embodiments of the post-compensation subsystem 350 can use the frequency domain signal to generate a post-compensation signal that can direct the clock generator 335 to shift the output frequency so as to compensate for at least a portion of the frequency drift of the crystal component 317. In some embodiments, the post-compensation signal is proportional to, or otherwise directly functionally related to the frequency domain signal. For example, the post-compensation signal indicates a frequency de-drift level having the same magnitude (or a multiplied magnitude, for example in accordance with a multiplier of the mapping subsystem 345) as that of the frequency domain signal, but in an opposite direction. In other embodiments, the post-compensation subsystem 350 is in communication with (and/or includes some or all of) the profile data store 347; and the profile data store 347 has a mapping stored thereon between particular values of the frequency domain signal and particular values of the post-compensation signal. For example, the post-compensation subsystem 350 can determine a value in a lookup table that is closest to a received frequency domain signal level, identify a particular digital bit value stored in the lookup table in association with the determined value, and generate the post-compensation signal to indicate the identified bit value.

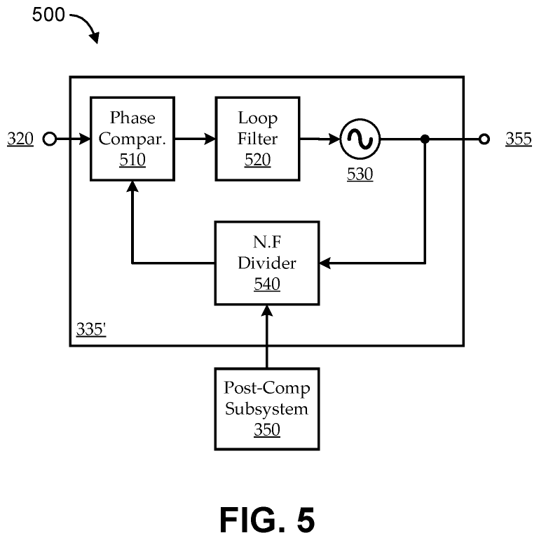

FIG. 5 shows a block diagram of an illustrative implementation of a portion of a clock system 500, according to some embodiments. The illustrated partial clock system 500 can be a portion of an implementation of the clock system 330 of FIG. 3. To avoid overcomplicating the figure, only the post-compensation subsystem 350 and a particular implementation of the clock generator 335 (indicated as 335′) are shown. The clock generator 335′ is implemented as a phase-locked loop (PLL) having a fractional divider block 540. Though not shown, the PLL can operate in context of a crystal oscillator (e.g., crystal oscillator circuit 310) that is generating a reference clock signal at a reference clock frequency, received by the PLL via node 320. The PLL includes a phase comparison block 510, a loop filter block 520, a voltage controlled oscillator (VCO) block 530, and a fractional divider block 540. The components are generally arranged in a feedback loop to regulate the output signal generated by the PLL at node 355. As described above, the PLL can generally seek to generate the output signal at an output frequency that is locked to a multiple of the reference frequency, and the multiple is typically a function of (e.g., the inverse of) a dividing value set by the fractional divider block 540. The dividing value is illustrated as “N.F,” where “N” refers to an integer component, and “F” refers to a fractional component. For example, if the reference clock signal is at 32 Megahertz, and N.F is ‘3.125’ (i.e., N is ‘3,’ and F is ‘125’), the PLL will lock the output clock signal at a frequency of 100 Megahertz (i.e., 32 times 3.125). The fractional divider block 540 can be implemented in any suitable manner. In some implementations, the fractional divider block uses delta-sigma modulation to effectively generate the fractional dividing value as an average over time. In other implementations, the fractional divider block uses periodic functions, or other approaches to effectively generate the fractional dividing value as an average over time.

In operation, the divider block 540 divides the frequency of the clock output signal by the dividing value and feeds it back to the phase comparison block 510. The phase comparison block 510 can include any suitable components, such as a phase/frequency detector (PFD), or the like, that receives the reference clock signal and compares the reference clock signal with the fed back signal from the divider block 540. The output of the phase comparison block 510 is a function of the comparison and is fed to the loop filter block 520, which can include any suitable components for facilitating filtering over the feedback loop, such as a charge pump and a low-pass filter. The output of the loop filter block 520 can be used to control the VCO block 530, which can include a ring oscillator and/or any other suitable VCO implementation to generate the output clock signal at node 355.

As described with reference to FIG. 3, the post-compensation subsystem 350 can generate a post-compensation signal that can direct the clock generator 335 to shift the output frequency so as to compensate for at least a portion of the frequency drift of the oscillator circuit 310 (due to frequency drift of the crystal component 317). In the illustrated clock system 500, the output of the post-compensation subsystem 350 is a signal to adjust the dividing value of the fractional divider block 540 of the PLL. In some embodiments, the fractional divider block 540 includes input nodes by which to assert one or more signals (e.g., corresponding to a digital value) that define “N” and “F” for the fractional divider block 540; and the post-compensation signal is coupled with one or both input nodes. In one implementation, the post-compensation signal is directly coupled to an input node that controls “F,” such that the post-compensation subsystem 350 directly adjusts the fractional component of the dividing value in a manner that compensates for some or all of any frequency drift of the oscillator circuit 310. In another implementation, the post-compensation subsystem 350 outputs the post-compensation signal as a word that defines the entire “N.F” dividing value. In other implementations, the post-compensation signal is received by one or more intermediate components that contribute to controlling “N” and/or “F.” For example, in some implementations, the dividing value of the PLL may be further modulated by one or more other signals (e.g., by a data signal), such that the “N.F” value is determined at any particular moment by multiple factors (e.g., by a desired carrier frequency, a data signal, and the post-compensation signal). In other embodiments, the post-compensation signal can be used to control one or more other components of the PLL (additionally or alternatively). For example, the post-compensation signal can be used to control a fine tuning parameter for the VCO block 530.

The various systems described above (e.g., with reference to FIGS. 1 and 3-5) can be implemented in various ways. For example, referring to FIG. 3, the clock system 330 can include (e.g., be implemented as) an integrated circuit having, integrated thereon, the measurement subsystem 340, the mapping subsystem 345, and the post-compensation subsystem 350. In some such embodiments, the integrated circuit can be a separate component from the oscillator circuit 310. For example, the clock system 330 is integrated on one integrated circuit, and the oscillator circuit 310 is integrated on another integrated circuit. In other such embodiments, some or all of the clock system 330 and the oscillator circuit 310 can be integrated onto a single integrated circuit and/or housed in a single component package. In some embodiments, the integrated circuit(s) can include one or more processors and non-transient, processor-readable memory. The memory can have instructions stored thereon, which, when executed, cause the one or more processors to implement functions of the measurement subsystem 340, the mapping subsystem 345, and the post-compensation subsystem 350. For example, one or more components of the clock system 330 can be processor-implemented. Further, though embodiments are illustrated and described as including particular blocks or components with particular respective functions, those blocks, components, and/or functions can be combined and/or distributed in any suitable manner. crystal system 305

Some embodiments described herein can also be integrated into other systems. Embodiments of the transceiver systems described with reference to FIG. 1 can include embodiments described herein. For example, the transmitter-side oscillator 110t of FIG. 1 can be implemented as the oscillator circuit 310 of FIG. 3 coupled with the crystal system 305 of FIG. 3, and the transmitter-side PLL 120t of FIG. 1 can be implemented in context of components of the clock system 330 of FIG. 3. In some such systems, the transmitter system includes a crystal system having, integrated therein, a crystal component and a thermistor; an oscillator circuit coupled with the crystal component to generate a clock reference signal at a reference frequency responsive to resonant oscillation of the crystal component; and a clock system. The clock system includes: a clock generator to couple with the oscillator circuit to generate a carrier signal at a carrier frequency responsive to receiving the clock reference signal from the oscillator circuit; a measurement subsystem to couple with the thermistor to measure an electrical domain level indicating a resistance of the thermistor; a mapping subsystem coupled with the measurement subsystem to generate a thermal domain signal indicating a temperature of the crystal component as a function of the resistance of the thermistor, and to generate a frequency domain signal indicating a frequency drift of the clock reference signal away from the reference frequency as a function of the temperature; and a post-compensation subsystem, coupled with the mapping subsystem and the clock generator, to output a post-compensation signal to the clock generator to direct the clock generator to shift the carrier frequency so as to compensate for at least a portion of the frequency drift in accordance with the frequency domain signal. As illustrated in FIG. 1, such a system can also include a modulator having a first modulator input to couple with the clock generator to receive the carrier signal, a second modulator input to receive a data signal, and a modulator output to output a transmission signal generated by modulating the carrier signal as a function of a digital frequency estimation of the data signal.

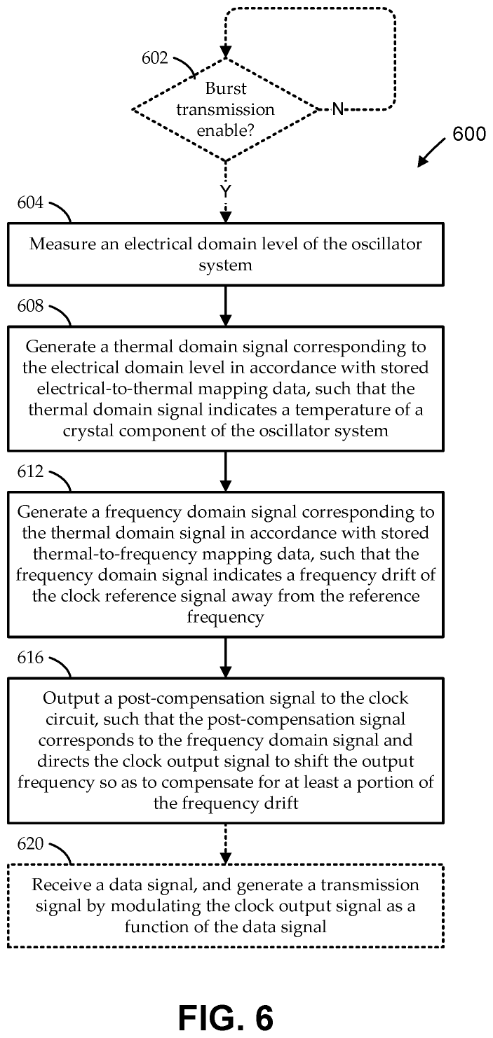

FIG. 6 shows a flow diagram of an illustrative method 600 for post-compensation of frequency drift in an oscillator system, according to various embodiments. The oscillator system can include a crystal component coupled with an oscillator circuit to drive the crystal component and output a signal that is responsive to resonant oscillations of the crystal component. The oscillator system can also include a thermal component positioned in close enough proximity to the crystal component, such that change in temperature of the thermal component is indicative of a corresponding change in temperature of the crystal component. For example, the oscillator system can be implemented as the crystal component 317 and thermal component 315 of the crystal system 305 of FIG. 3, along with the oscillator circuit 310 of FIG. 3. As described above, though the oscillator system is being described as including those components, the crystal component 317 and the thermal component 315 are likely implemented in a single physical package, while the oscillator circuit 310 is likely implemented separately therefrom. Embodiments of the method 600 can operate in context of the oscillator circuit outputting a clock reference signal at a reference frequency, such that the clock reference signal is usable by a clock circuit to generate a clock output signal at an output frequency. Embodiments of the method 600 can begin at stage 604 by measuring an electrical domain level of the oscillator system.

At stage 608, embodiments can generate a thermal domain signal corresponding to the electrical domain level in accordance with stored electrical-to-thermal mapping data. The generated thermal domain signal can indicate a temperature of a thermal component, which can correspond to a temperature of a crystal component of the oscillator system. In some embodiments, the oscillator system includes a thermistor, and measuring the electrical domain level at stage 604 can include measuring a resistance of the thermistor. For example, measuring the resistance of the thermistor at stage 604 can include driving a current signal through the thermistor, measuring a voltage signal across the thermistor responsive to the current signal, and deriving the resistance of the thermistor from the current signal and the voltage signal. In such embodiments, generating the thermal domain signal at stage 608 can include mapping the resistance of the thermistor to a temperature of the thermistor in accordance with the stored electrical-to-thermal mapping data.

At stage 612, embodiments can generate a frequency domain signal corresponding to the thermal domain signal of the oscillator system in accordance with stored thermal-to-frequency mapping data. The frequency domain signal can indicate a frequency drift of the clock reference signal away from the reference frequency. At stage 616, embodiments can output a post-compensation signal to the clock circuit. The post-compensation signal can correspond to the frequency domain signal and can direct the clock output signal to shift the output frequency so as to compensate for at least a portion of the frequency drift. In some embodiments, the clock generator includes a phase-locked loop (PLL) that generates the clock output signal, such that the output frequency is a function of the reference frequency and a dividing value. In such embodiments, the post-compensation signal can direct the divider block to adjust the dividing value thereby to shift the output frequency so as to compensate for the at least a portion of the frequency drift. In some embodiments, the method 600 can further include functions relating to integration with a transmitter, or the like. For example, some embodiments can continue at stage 620 by receiving a data signal, generating a transmission signal by modulating the clock output signal as a function of the data signal (e.g., and/or by transmitting the data signal over a transmission channel).

In some embodiments, the method 600 begins at stage 602 (rather than at stage 604) by detecting a transmission enable signal indicating temporary activation of the transmitter. For example, in embodiments that are part of a transmitter, and the transmitter is used for burst transmissions, it can be desirable only to perform stages of the method during transmission (e.g., the crystal oscillator is unlikely to experience thermal drift, and/or the thermal drift is not likely to have an impact, when the transmitter is not transmitting). In such embodiments, a determination can be made as to whether the transmission enable signal is detected. If not, embodiments can continue to wait for such a detection without performing stages of the method 600. Otherwise, at least some of stages 604-616 can be performed in response to the detecting at stage 602 (e.g., only when the transmitter is active).

It will be understood that, when an element or component is referred to herein as “connected to” or “coupled to” another element or component, it can be connected or coupled to the other element or component, or intervening elements or components may also be present. In contrast, when an element or component is referred to as being “directly connected to,” or “directly coupled to” another element or component, there are no intervening elements or components present between them. It will be understood that, although the terms “first,” “second,” “third,” etc. may be used herein to describe various elements, components, these elements, components, regions, should not be limited by these terms. These terms are only used to distinguish one element, component, from another element, component. Thus, a first element, component, discussed below could be termed a second element, component, without departing from the teachings of the present invention. As used herein, the terms “logic low,” “low state,” “low level,” “logic low level,” “low,” or “0” are used interchangeably. The terms “logic high,” “high state,” “high level,” “logic high level,” “high,” or “1” are used interchangeably.

As used herein, the terms “a”, “an” and “the” may include singular and plural references. It will be further understood that the terms “comprising”, “including”, having” and variants thereof, when used in this specification, specify the presence of stated features, steps, operations, elements, and/or components, but do not preclude the presence or addition of one or more other features, steps, operations, elements, components, and/or groups thereof. In contrast, the term “consisting of” when used in this specification, specifies the stated features, steps, operations, elements, and/or components, and precludes additional features, steps, operations, elements and/or components. Furthermore, as used herein, the words “and/or” may refer to and encompass any possible combinations of one or more of the associated listed items.

While the present invention is described herein with reference to illustrative embodiments, this description is not intended to be construed in a limiting sense. Rather, the purpose of the illustrative embodiments is to make the spirit of the present invention be better understood by those skilled in the art. In order not to obscure the scope of the invention, many details of well-known processes and manufacturing techniques are omitted. Various modifications of the illustrative embodiments, as well as other embodiments, will be apparent to those of skill in the art upon reference to the description. It is therefore intended that the appended claims encompass any such modifications.

Furthermore, some of the features of the preferred embodiments of the present invention could be used to advantage without the corresponding use of other features. As such, the foregoing description should be considered as merely illustrative of the principles of the invention, and not in limitation thereof. Those of skill in the art will appreciate variations of the above-described embodiments that fall within the scope of the invention. As a result, the invention is not limited to the specific embodiments and illustrations discussed above, but by the following claims and their equivalents.

What is claimed is:

1. A clock system comprising:
a clock generator to couple with an oscillator circuit and to generate a clock output signal at an output frequency responsive to receiving, from the oscillator circuit, a clock reference signal at a reference frequency, the clock reference signal generated by the oscillator circuit responsive to resonant oscillation of a crystal component coupled to the oscillator circuit;
a measurement subsystem to couple with a thermal component to measure an electrical domain level of the thermal component;
a mapping subsystem coupled with the measurement subsystem to:
generate a thermal domain signal corresponding to the electrical domain level in accordance with stored electrical-to-thermal mapping data for the thermal component, such that the thermal domain signal indicates a temperature of the thermal component, the thermal component being disposed in proximity to the crystal component, such that a change in temperature of the thermal component indicates a corresponding change in temperature of the crystal component; and
generate a frequency domain signal corresponding to the thermal domain signal in accordance with stored thermal-to-frequency mapping data, such that the frequency domain signal indicates a frequency drift of the clock reference signal away from the reference frequency; and
a post-compensation subsystem, coupled with the mapping subsystem and the clock generator, to output a post-compensation signal to the clock generator, such that the post-compensation signal corresponds to the frequency domain signal and directs the clock generator to shift the output frequency so as to compensate for at least a portion of the frequency drift.

2. The clock system of claim 1, wherein:
the thermal component is a thermistor;
the measurement subsystem is to measure the electrical domain level to indicate a resistance of the thermistor; and
the mapping subsystem is to generate the thermal domain signal by mapping the resistance of the thermistor to a temperature of the thermistor in accordance with the stored electrical-to-thermal mapping data.

3. The clock system of claim 2, wherein the measurement subsystem is to measure the electrical domain level to indicate the resistance of the thermistor by:
driving a current signal through the thermistor;
measuring a voltage signal across the thermistor responsive to the current signal; and
deriving the resistance of the thermistor from the current signal and the voltage signal.

4. The clock system of claim 1, wherein:
the clock generator comprises a phase-locked loop (PLL), an input of the PLL to receive the clock reference signal from the oscillator circuit, and an output of the PLL to output the clock output signal.

5. The clock system of claim 4, wherein:
the PLL comprises a divider block to define a dividing value, such that the output frequency is a function of the reference frequency and the dividing value; and
the post-compensation subsystem is to couple with the divider block, such that the post-compensation signal directs the divider block to adjust the dividing value thereby to shift the output frequency so as to compensate for the at least a portion of the frequency drift.

6. The clock system of claim 5, wherein:
the divider block is a delta-sigma fractional divider block;
the dividing value has an integer component and a fractional component; and
the fractional component is controlled at least by the post-compensation signal.

7. The clock system of claim 1, wherein the mapping subsystem further comprises:
a mapping data store having, stored thereon, the electrical-to-thermal mapping data for the thermal component and the thermal-to-frequency mapping data for the crystal component.

8. The clock system of claim 7, wherein:
the electrical-to-thermal mapping data for the thermal component is stored as a lookup table having a plurality of measured electrical values for the thermal component, each stored in association with a corresponding one of a plurality of temperature values for the thermal component; and
the mapping subsystem is to generate the thermal domain signal by:
identifying one of the plurality of measured electrical values in the lookup table as closest to the electrical domain level;
identifying the corresponding one of the plurality of temperature values stored in the lookup table in association with the identified one of the plurality of measured electrical values; and
generating the thermal domain signal to indicate the temperature of the crystal component as the identified corresponding one of the plurality of temperature values.

9. The clock system of claim 1, further comprising:
an integrated circuit having, integrated thereon, the measurement subsystem, the mapping subsystem, and the post-compensation subsystem, the integrated circuit being a separate component from the crystal component and the thermal component.

10. The clock system of claim 9, wherein the integrated circuit further has the clock generator integrated thereon.

11. The clock system of claim 9, wherein the integrated circuit further has the oscillator circuit integrated thereon.

12. The clock system of claim 9, wherein the integrated circuit further comprises:
one or more processors; and
non-transient, processor-readable memory having instructions stored thereon, which, when executed, cause the one or more processors to implement the measurement subsystem, the mapping subsystem, and the post-compensation subsystem.

13. A transmitter system comprising:
a crystal system having, integrated therein, a crystal component and a thermistor;
an oscillator circuit coupled with the crystal component to generate a clock reference signal at a reference frequency responsive to resonant oscillation of the crystal component; and
a clock system comprising:
a clock generator to couple with the oscillator circuit to generate a carrier signal at a carrier frequency responsive to receiving the clock reference signal from the oscillator circuit;
a measurement subsystem to couple with the thermistor to measure an electrical domain level indicating a resistance of the thermistor;
a mapping subsystem coupled with the measurement subsystem to generate a thermal domain signal indicating a temperature of the crystal component as a function of the resistance of the thermistor, and to generate a frequency domain signal indicating a frequency drift of the clock reference signal away from the reference frequency as a function of the temperature; and
a post-compensation subsystem, coupled with the mapping subsystem and the clock generator, to output a post-compensation signal to the clock generator to direct the clock generator to shift the carrier frequency so as to compensate for at least a portion of the frequency drift in accordance with the frequency domain signal.

14. The transmitter system of claim 13, further comprising:
a modulator having a first modulator input to couple with the clock generator to receive the carrier signal, a second modulator input to receive a data signal, and a modulator output to output a transmission signal generated by modulating the carrier signal as a function of the data signal.

15. A method for post-compensation of frequency drift in an oscillator circuit that outputs a clock reference signal at a reference frequency, such that the clock reference signal is usable by a clock circuit to generate a clock output signal at an output frequency, the method comprising:
measuring an electrical domain level of an oscillator system comprising a crystal component, a thermal component, and an oscillator circuit;
generating a thermal domain signal corresponding to the electrical domain level in accordance with stored electrical-to-thermal mapping data, such that the thermal domain signal indicates a temperature of the crystal component;
generating a frequency domain signal corresponding to the thermal domain signal in accordance with stored thermal-to-frequency mapping data, such that the frequency domain signal indicates a frequency drift of the clock reference signal away from the reference frequency; and
outputting a post-compensation signal to the clock circuit, such that the post-compensation signal corresponds to the frequency domain signal and directs the clock output signal to shift the output frequency so as to compensate for at least a portion of the frequency drift.

16. The method of claim 15, wherein:
the thermal component is a thermistor;
measuring the electrical domain level comprises measuring a resistance of the thermistor; and
generating the thermal domain signal comprises mapping the resistance of the thermistor to a temperature of the thermistor in accordance with the stored electrical-to-thermal mapping data.

17. The method of claim 15, wherein measuring the resistance of the thermistor comprises:
driving a current signal through the thermistor;
measuring a voltage signal across the thermistor responsive to the current signal; and
deriving the resistance of the thermistor from the current signal and the voltage signal.

18. The method of claim 15, wherein:
the clock generator comprises a phase-locked loop (PLL) that generates the clock output signal, such that the output frequency is a function of the reference frequency and a dividing value; and
the post-compensation signal directs the divider block to adjust the dividing value thereby to shift the output frequency so as to compensate for the at least a portion of the frequency drift.

19. The method of claim 15, wherein the clock circuit and the oscillator system are part of a transmitter circuit, and further comprising:
detecting a transmission enable signal indicating temporary activation of the transmitter for a burst transmission,
wherein at least some of the steps of measuring the electrical domain level, generating the thermal domain signal, generating the frequency domain signal, and outputting the post-compensation signal are performed in response to the detecting.

20. The method of claim 15, wherein the clock circuit and the oscillator system are part of a transmitter circuit, and further comprising:
receiving a data signal; and
generating a transmission signal by modulating the clock output signal as a function of a digital frequency estimation of the data signal.
